(19) United States
(12) Patent Application Publication
(10) Pub. No.: US 2012/0268864 A1
(43) Pub. Date: Oct. 25, 2012

(54) APPARATUS HAVING PLURALITY OF OPENINGS TO ACCESS REMOVABLE ELECTRONIC DEVICES SOME OF WHICH HAVE ELECTRICAL CONNECTIONS USING NO CIRCUIT BOARD TRACE

(75) Inventors: THEODORE J. BOROWICZ, Flat Rock, MI (US); RUBEN AVILA, CD. JUAREZ (MX); EDUARDO NUNEZ, EL PASO, TX (US); ERICK GONZALEZ, CD. JUAREZ (MX); CRISTINA G. CUARON, EL PASO, TX (US); RAY N. RAUTIO, REDFORD, MI (US)

(73) Assignee: DELPHI TECHNOLOGIES, INC., TROY, MI (US)

(21) Appl. No.: 13/091,304

(22) Filed: Apr. 21, 2011

(51) Int. Cl. H05K 7/00; H02B 1/00

(52) U.S. Cl. 361/601; 361/679.01; 361/752

(57) ABSTRACT

An electrical current-carrying apparatus includes a housing containing a plurality of electronic devices that also includes a plurality of removable electronic devices. The housing further defines a plurality of openings so that the removable devices are accessible through at least one of the plurality of openings. The housing receivably couples at least one wire cable that is in electrical communication with the electronic devices. When the at least one wire cable is receivably coupled to the housing and the at least one removable device needs accessed, the at least one removable electronic device is accessed through at least one of the plurality of openings while the at least one coupled wire cable remains attached to the housing. A relay and fuse electronic circuit arrangement and a fuse electronic circuit arrangement each effectively utilize the allotted packaging space within the apparatus while also conserving the use of circuit board trace.

### TECHNICAL FIELD

This invention relates to electrical distribution centers.

### BACKGROUND OF INVENTION

Electrical distribution centers are widely used in the automotive industry.

Electrical centers provide and manage current flow to the many electrical components in electrical connection with the electrical center generally from a common power source. Electrical centers provide a centralized location for a population of electronic components including removable electronic components like removable relays, removable fuses, and the like. The challenge remains to centralize and fit the plethora of removable electronic components resulting from increased electrical content in a vehicle into an allotted volume of packaging space in the vehicle may not have similarly increased. It remains desirable to have accessibility to the removable electronic components if service to these removable components is required. The removable components may also be required to be accessible while the population of electronic components in the electrical center remain electrically powered by, and in electrical communication with wire cables attached to the electrical center. Providing the centralized location to package the removable electronic devices may also desirably free up packaging space elsewhere in the vehicle that might otherwise be used to package clusters of removable electronic devices which may also decrease the material, assembly, and serviceability costs associated with a multiple location packaging approach.

Thus, what is needed is a robust electrical current-carrying apparatus that allows packaging an increased of removable electronic components that are easily accessed through a plurality of openings in the apparatus regardless of the number of openings defined in the apparatus while these electronic components disposed in the apparatus remain electrically energized.

### SUMMARY OF THE INVENTION

One aspect of the invention is to safely and reliably access an increased amount of electronic devices that also include an increased amount of removable electronic devices in an electrical current-carrying apparatus in a packaging space that generally has not increased in volume. Another aspect of the invention is packaging the increased amount of removable electronic devices in a manner so that the removable electronic devices are easily accessed by a human operator using only the human operator's hands. In yet another aspect, accessing any of the removable electronic devices while at least one wire cable remains electrically connected to the electrical devices of the apparatus is also desired. To this end, another aspect of the invention is the discovery of electronic device packaging arrangements that satisfactorily intersect all of these aforementioned aspects. One electronic device arrangement disposed in the apparatus includes two or more removable electronic devices that may be advantageously densely bundled together in a compact space where at least one of the electrical connections in the arrangement does not require the use of circuit board trace during the construction of the arrangement. An electronic fuse arrangement may also be advantageously densely bundled together while also being packaged within the apparatus in an area of the apparatus that opposes connector ports disposed on the apparatus. The connector ports of the apparatus receive wire cables that electrically communicate with the electronic devices of the apparatus. This fuse device arrangement, then, allows efficient use of the allotted space in the apparatus beneath the connector port. Based on the desire to have accessibility to any of the removable electronic devices by a human operator without using a tool while the electronic devices remain in electrical communication to the at least one wire connector, and in accordance with one embodiment of the invention, an electrical current-carrying apparatus includes a housing containing a plurality of electronic devices including removable electronic devices that are disposed in the housing. The housing defines a plurality of openings so that the removable electronic devices are accessible through at least one of the plurality of openings. The housing is configured to receivably couple at least one wire cable so that the at least one coupled wire cable is in electrical communication with at least one electronic device in the plurality of electronic devices. When the at least one wire cable is recievably coupled to the housing and the at least one removable device needs accessed, the at least one removable electronic device is accessed through at least one of the plurality of openings while the at least one coupled wire cable remains attached to the housing.

These and other advantageous features as disclosed in the embodiments of the present invention will be become apparent from the following brief description of the drawings, detailed description, appended claims and drawings.

### BRIEF DESCRIPTION OF THE DRAWINGS

This invention will be further described with reference to the accompanying drawings in which:

FIG. 1 shows an electrical current-carrying apparatus that is a power distribution box (PDB) disposed an engine compartment of a vehicle in accordance with an embodiment of the invention;

FIG. 2 shows a magnified view of the PDB of FIG. 1;

FIG. 3 shows electrical components disposed adjacent a first opening of the PDB of FIG. 2, with the removable cover removed;

FIG. 4 shows removable electrical components disposed adjacent a second opening of the PDB of FIG. 2, with the removable cover removed;

FIG. 5 shows a side view of the PDB of FIG. 2 being removed from a bracket secured in the engine compartment;

FIG. 6 shows accessing removable electrical components through the first and the second opening by flippingly moving the PDB of FIG. 2 about the at least one coupled wire cable that remains attached to the PDB;

FIG. 7 shows an electronic circuit arrangement disposable in the PDB of FIG. 2, and details thereof;

FIG. 8 shows a topical view electrical schematic diagram of the electronic circuit arrangement of FIG. 7;

FIG. 9 shows a removable fuse circuit arrangement disposed within an area of the PDB of FIG. 2 underlying the connector port of the PDB that receivably couples a wire cable;

FIG. 10 shows a method to access the removable devices through one of the plurality of openings defined in the apparatus of FIG. 1; and

FIG. 11 shows a method to operate the apparatus of FIG. 1 that includes at least one electrical circuit arrangement that has at least one axially-aligned electrical connection.

### DETAILED DESCRIPTION

An electrical current-carrying apparatus may supply power and control electrical signals to various electrical systems in the vehicle such as ignition systems, anti-lock braking systems, fuel systems, and air conditioning systems. Such an electrical current-carrying apparatus in the automotive industry is appropriately named as an electrical center, a bussed electrical center (BEC), or a power distribution box (PDB). These PDBs may carry, or transmit hundreds of amperes of electrical current that is metered, or parsed out to different electrical components or systems. Such electrical components or systems may include and are not limited to heated seats, defrosters, windshield wipers, ignition starter cores and the like, that may operate in the vehicle through independent fuses or switched power electrical circuits. With the continued increase in electrical content of the vehicle, more electrical devices including removable electrical devices, require packaging somewhere within the vehicle space where packaging space for these removable devices is increasingly limited. For example, the volume to package a PDB in an engine compartment may be limited and constrained due to other physical structures that take up space within the engine compartment, such as shock towers, headlight assemblies, other engine components, and even the vehicle's exterior contour design shape. This packaging space, perhaps, may be even more constricted and limited in an engine compartment of the vehicle. Desirably, an under-hood PDB provides a central location for the collection of these removable electronic devices while also being located proximate electronic engine components that are electrically connected to the PDB. Co-location of other removable electronic components in electrical connection with electrical components or electrical systems external to the engine compartment may also be desirably located in the PDB.

The following terms used in this specification have the following definitions:

Access, Accessibility—This term refers to a removable electronic device that is disposed in the electrical current-carrying apparatus may be visually seen in the electrical current-carrying apparatus by a human eye of a human operator so that the removable electronic devices may be removed/replaced in the apparatus through the plurality of openings of the apparatus.

Double-ended terminal—A double-ended terminal has terminal ends where one terminal end is attachable to a terminal of one removable device and another terminal end is attachable to an opposing removable device. At least one terminal end of the double-ended terminal may also be attachable with a terminal that is part of a connector, which is for example, attached to a wire cable. Either terminal end of the double-ended terminal may be a male or female-type terminal. The male terminal may be a blade terminal. The double-ended terminal may also be soldered to the PCB to provide further mechanical support for the double-ended terminal.

Electric-current carrying apparatus—An electrical current-carrying apparatus that experiences the movement of electrons through the apparatus that has a unit of measure in amperes.

Electronic device—An electronic device may be part of an electrical circuit or system that uses the principle of electron flow through the electronic device. For instance, electrical devices may be generally fixedly secured to a printed circuit board by being soldered to the printed circuit board. An electrical device may also be a removable electrical device that generally is not directly soldered to the printed circuit board so as to be more easily removed if the removable electronic device needs serviced to replace a faulty device. Examples of electrical devices may include resistors, capacitors, inductors, transistors, relays, fuses, and the like.

Footprint of an electronic device—The space created by an electronic device as occupied by the electrical device that has a size and a shape of an area that the electrical device occupies. If the electrical device is disposed on a printed circuit board adjacent to the circuit board the two-dimensional, surface area created on the printed circuit board by the disposed electronic device may be referred to as the electronic device's footprint. The footprint of an electrical device may also be that two-dimensional, surface area which is extended on to an external surface of the printed circuit board by a plane generally perpendicular to the surface of the circuit board of the electronic device located proximate the printed circuit board.

Removable electrical device—An electrical device that is removable is easily renewable. A renewable device may be readily restored to operation by replacement in its place of origin in an electrical circuit with a similar electronic device. Such a removable electronic device is generally not fixedly secured to a position in an electrical circuit, such as when directly soldered to a printed circuit board, but may require a non-soldering iron type tool such as a fuse puller, or pliers to remove/replace the removable electronic device from its place of origin in the electrical circuit. The tool would also need to fit through the plurality of openings in the electrical current-carrying apparatus to remove/replace the removable electronic device. Removable relay devices and removable fuse devices are typical removable electronic devices.

Tool—Anything held in the human hands of a human operator that assists the human operator to access removable electronic devices through the plurality of openings of the electrical current-carrying apparatus. Examples of tools may be picks, screwdrivers, pliers, wrenches, et cetera. Once the removable electronic device is accessed through one of the plurality of openings, a tool may be used to remove/replace the removable electronic device through the plurality of openings of the electrical current-carrying apparatus.

Tool, Special—Anything held in the human hands of a human operator that assists the human operator to conduct manual work. More specifically, a special tool formed in a manner so as to have a generally single purpose and keep other human operators who do not possess the special tool from conducting the manual work. For example, special tools may generally prevent serviceability work to the electrical current-carrying apparatus in a vehicle except by a human operator or service technician who possess and employ the use of the special tool during service to the electrical current-carrying apparatus.

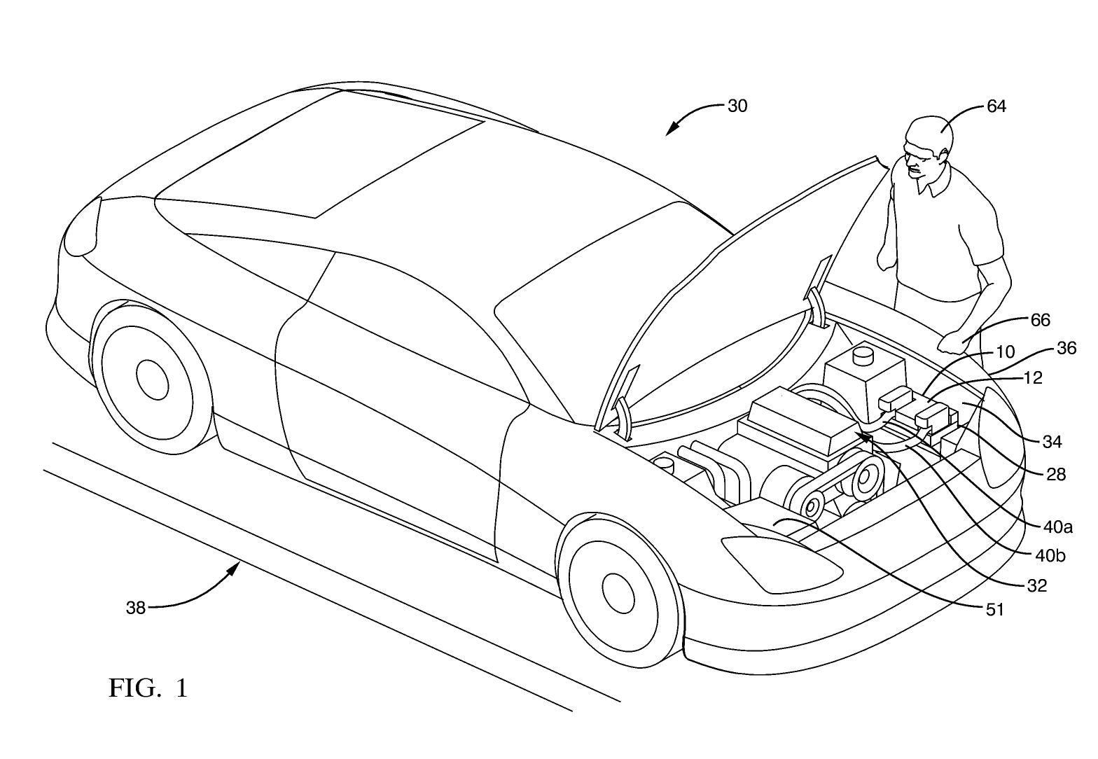

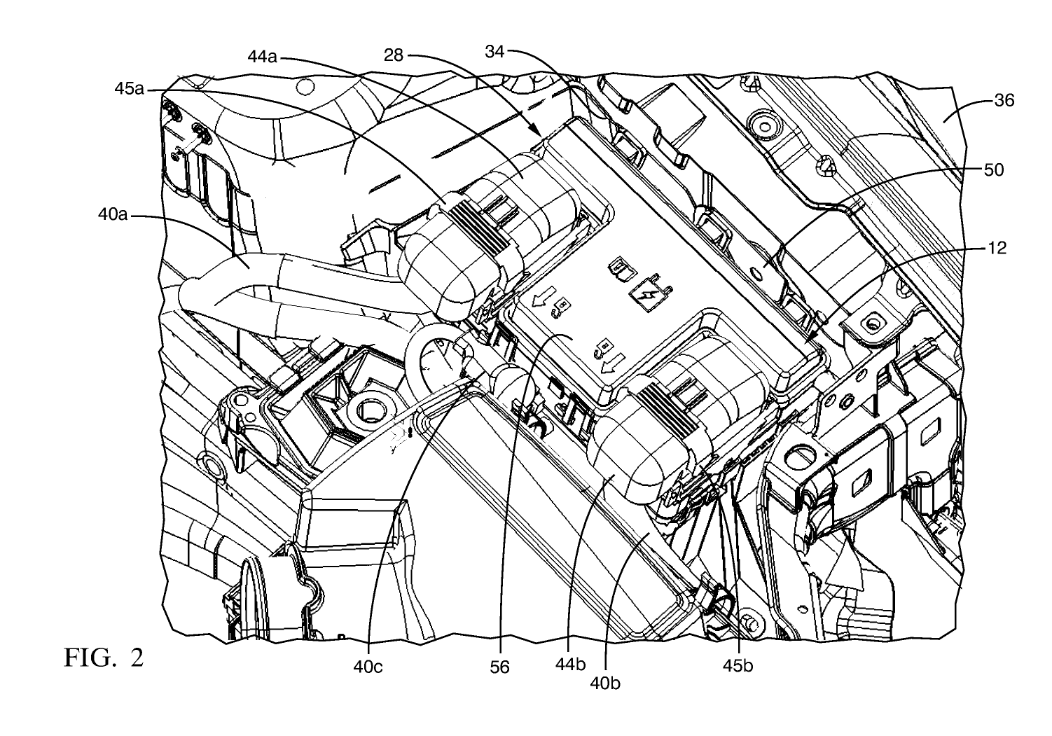

In accordance with a one embodiment of this invention, referring to FIGS. 1-11, an electrical-current carrying apparatus 10 is presented. Apparatus 10 is a power distribution box (PDB) 12 that includes a plurality of electronic devices 14 at least some of which are one or more, or a plurality of removable electronic devices 16. Referring to FIG. 2, PDB 12 has a rectangular shape. Housing 18 is further formed from an upper housing 19 attached to a lower housing 21. Upper and lower housing 19, 21 are attached together by a plurality of housing lock tabs 52 that surround a perimeter of PDB 12. Tabs 52 are mechanically press-fit by a machine and are not meant to be opened by using only the human hands a human operator 64. Tabs 52 may require a special tool to actuate tabs 52 and separate upper housing 19 from lower housing 21.

Housing 18 of apparatus 10 includes at least a first housing wall 20 formed in upper housing 19 and a second housing wall 22 formed in lower housing 21. Second housing wall 22 is opposite first housing wall 20. First wall 22 defines at a first opening 24 and second wall 22 defines a second opening 26. Housing 18 may be formed by injection molding by methods known in the molding arts. Openings 24, 26 provide accessibility to remove and renew any of the plurality of removable devices 16 through plurality of openings 24, 26 external to housing 18.

PDB 12 is associated with a power distribution system 28 in vehicle 30 disposed in an engine compartment 32 of a vehicle 30 that includes a hydrocarbon fuel engine. Power distribution system 28 at least further includes the wiring and electrical connections disposed in vehicle 30 that interface with PDB 12. Alternately, the powertrain of the vehicle may be operated, or driven by an electric motor or a combination of an electric motor and a hydrocarbon fuel engine typically known as a hybrid vehicle. The hybrid vehicle may be a plug-in electric vehicle where a power supply cord is coupled to the vehicle to electrically charge the battery of the vehicle. Still yet alternately, the PDB may be located anywhere in the vehicle, such as perhaps suitably being disposed in the trunk or rear cargo area of the vehicle. Power distribution box 12 is disposed along an exterior wall 34 of engine compartment 32 adjacent an outer exterior wall 32 of vehicle 30. Vehicle 30 is disposed on a generally planar ground surface 38. First wall 20 is generally remote from ground surface 38 in a direction generally perpendicular to ground surface 38 and second wall 22 is intermediate first wall 20 and ground surface 38. First wall 20 and second wall 22 are generally parallel with ground surface 38.

Referring to FIGS. 2, 3, and 9, wire conductors 41 disposed in two wire cables 40a, 40b terminate and are attached in corresponding mating connectors 48 that are coupled to, and received by respective connector ports 42 along first wall 20 of PDB 12. Alternately, any number of connector ports may be disposed on the PDB and receive any number of connectors that are attached to any number of wire cables. Wire cable 40c connects a power supply source to PDB 12 terminating in a lug (not shown) that is fastened to a mechanical bolt 51 disposed on PDB 12 adjacent housing 18. This power supply source provides a power source 86 for PDB 12 and power source 86 may take the form of a power bus bar disposed within the PDB. For example, the power supply source may be directly supplied from the B+, or positive terminal of the battery of the vehicle. Alternately, a power source supplied to the PDB may be fuse protected. Still yet alternately, the power supply source from the battery may be indirectly or directly supplied to the PDB through the wire cables or in any other possible configuration as required for a specific electrical application where the PDB may be employed. In another embodiment, the power supply source for the PDB may be supplied to the PDB through other electronic components, modules, or systems disposed in the vehicle.

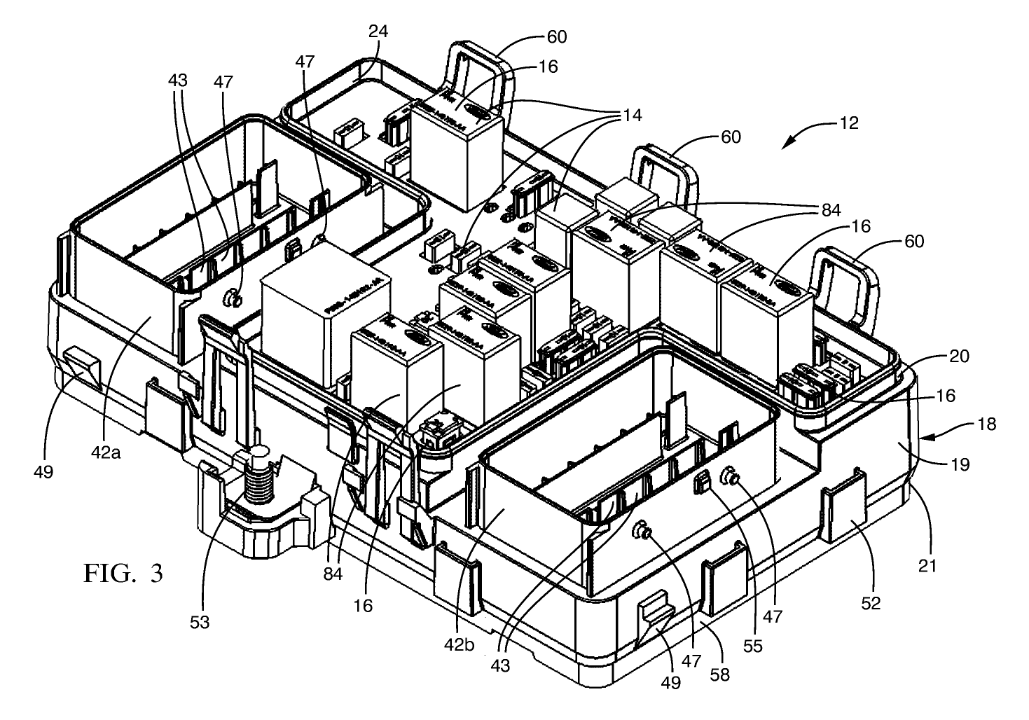

A plurality of wire cable connector covers 44a, 44b attach with respective coupled connectors 48 to overlie connector 48 and connector port 42 when connectors 48 are attached to connector ports 42. Covers 44 provide splash-proof protection from environmental elements, such as water, from penetrating in PDB 12. Covers 44a, 44b attach mating connectors 48 with respective manually releasable latches 45a, 45b to secure mating connectors 48 and covers 44 to connector mechanical lever assist pins 47 projecting from connector ports 42. Using at least one human hand 66, human operator 64 may engage latches 45 to release covers 44 and expose openings 24, 26. Covers 44 are distinct from connectors 48 where connectors 48 also include a seal (not shown) that further keep environmental elements from entering PDB 12 or terminals at connector ports 42 when covers 44 are attached with connector ports 42. As covers 44 are void of hinges, a simpler mold may be constructed to injection mold covers 42 which may decrease manufacturing costs to construct the covers. Alternately, the covers covering the openings may be hinged covers and the hinge may communicate with the housing. Lever lock actuation tab 55 provides a way to unlock securing latches 45 from pins 47 and release connectors 48 and corresponding wire cables 40 from PDB 12. Referring to FIG. 3, connector ports 42a, 42b each include electrically-conductive terminals 43 that electrically interface with electrically-conductive terminals in connectors 48 that are electrically connected to wire conductors 41 of respective wire cables 40a, 40b. Thus, when wire cables 40a, 40b, 40c are attached with PDB 12, wire cables 40a, 40b, 40c electrically interface and have electrical conductivity with the electronic circuits and at least one electronic device in plurality of electronic devices 14 disposed in PDB 12 with electrical components and systems disposed on vehicle 30. The connector ports may be sized to include any number of terminals as is required for a specific electrical application.

And being disposed in along first wall 20, wire cables 40 are positioned to form a semi-circular shape that depends away from first wall 20 of PDB 12 to form a natural run-off, gravity-draining drip-loop mechanization. This drip-loop mechanization of wire cables 40 may be useful to prevent further environmental elements from possible intrusion towards housing 18 that provides for a more robust PDB 12 as the environmental elements will wick harmlessly in a downward direction along wire cables 40 away from PDB 12. Openings 24, 26 provide accessibility to remove and renew any of removable devices 16 through plurality of openings 24, 26 in housing 18 while wire cables 40 remain coupled to apparatus 10 and remain in electrical communication with at least one electrical device in plurality of electrical devices 14. Coupled wire cables 40 are useful to ensure electrical operation of electrical devices 16 disposed in apparatus 10 that may be readily diagnosable by a human operator 64. If wire cables 40 are unconnected from apparatus 10, apparatus 10 may at least be partially or totally electrically inoperative such that electrical devices 14 may undesirably not be electrically diagnosable by human operator 64. For example, the human operator may be an owner of vehicle 30 that may service removable devices 16. In another example, human operator 64 may also be a service technician or a vehicle assembly plant technician.

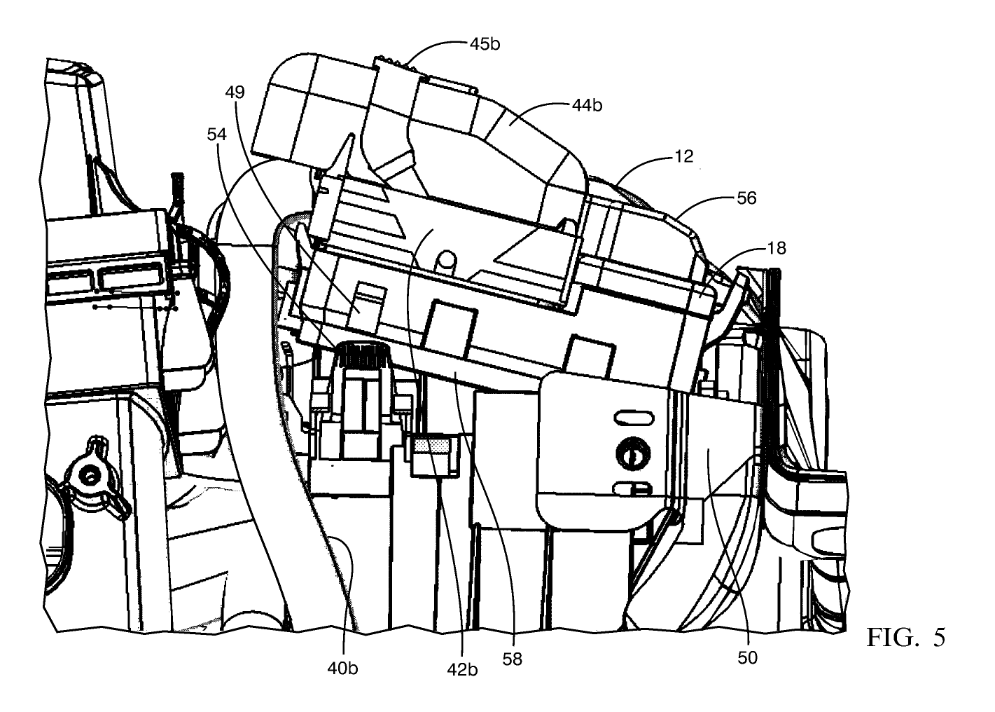

Power distribution system 28 also includes a bracket 50 and PDB 12 is removably coupled to bracket 50. Referring to FIGS. 2 and 5, PDB 12 is recievably coupled and secured to bracket 50 by a finger-actuated tabs 54 disposed on bracket 50 that are received by in-board lock wedges 49 disposed along an exterior surfaces of upper housing 19. Upper housing 19 of PDB 12 is formed of a first dielectric material and lower housing 21 is formed of a second dielectric material different from the first dielectric material. Alternately, the upper and lower housing of the PDB may be formed of plastic material where additives may be added for increased temperature resistance or strength. Still yet alternately, the upper and lower housing may be constructed from the same material. In one embodiment the upper and lower housing may be formed from a 14% glass filled plastic material. Bracket 50 may also be injection molded and may be formed of any of the materials use to form housing 18 as previously discussed herein. Alternately, bracket may be formed from any type of plastic material with or without additives for strength improvement or for enhanced performance under high or low operating temperature. Preferably, housing 19, 21 are formed from any dielectric material that may be application specific. Upper housing 19 may be constructed of a material so that the mechanical forces needed to attach connectors 48 of wire cable 40 to connector port 42 will not cause damage to cams 47 disposed on connector ports 42 with repeated mating of connectors 48 of wire cables 40. Connector 48a of wire conductor 40a is keyed to fit connector port 42a and the connector (not shown) of wire cable 40b is keyed to fit connector port 40b.

Walls 20, 22 have a parallel, spaced apart relationship. Openings 24, 26 correspondingly have a similar parallel relationship. As viewed looking into engine compartment 32, PDB 12 has a rectangular shape as best illustrated in FIG. 2. The shape of first opening 24 forms a T-shape, with the T-shape being further formed and bounded as such by connector ports 42. The shape of second opening 26 does not minor the T-shape of first opening 24, but rather is generally the rectangular shape of PDB 12. Thus, the surface area to access removable devices 16 is greater through second opening 26 than through first opening 24. Alternately, the openings disposed in the housing may be any geometrical shape and the shapes used for the plurality of openings on the PDB may be dictated by the electrical application or be orientation specific.

A first removable cover 56 is configurable to cover and fit first opening 24 and second removable cover 58 is configured to cover and fit second opening 26. Covers 56, 58 are formed of a similar material as that of housings 19, 21, as previously described herein. The different shapes of openings 24, 26 ensure covers 56, 58 only fit the specific opening 24, 26 in a single orientation. Covers 56, 58 prevent undesired environmental elements, such as water, dirt, and engine lubricants like oil and grease, from entering housing 18 through first and second opening 24, 26. Covers 56, 58 include clips 60 for snap-fitting covers 56, 58 to clips 60 disposed on housing 18 adjacent openings 24, 26. Thus, covers 56, 58 are individually removably coupled, or attached to housing 18. Referring to FIG. 2, markings on covers 56, 58 may be employed to assist human operator 64 to open covers 56, 58 and assist human operator 64 in removable electronic device identification. These visible markings may be inscribed on the external outward surface of these removable covers by being molded, laser etched, pad printed, or screen printed. Alternately, visible markings may be included on the opposite, or inside internal portion of the removable covers that face inward the PDB when attached to the PDB. The T-shape of first removable cover 56 ensures removable cover 56 is replaced to cover first opening 24 in a correct, single orientation. Multiple tabs orientated about a peripheral edge of second cover 58 ensure second cover 58 is replaced to cover second opening 26 in a correct, single orientation. Covers 56, 58 are removable by a human operator without the use of a tool (not shown) or a special tool, preferably only using at least one human hand 66 of human operator 64. For instance, the tool may be a screwdriver, a metal pick, pliers, wrenches, or one the many special tools used in the automotive industry, and the like. Removing and attaching covers 56, 58 by using at least one human hand 66 of human operator 64 saves time in accessing the removable electronic devices as human operator 64 does not also need to remember to procure tools or special tools. Special tools generally also have an undesired cost incurred to procure the special tool. PDB 12 may be manipulated, removed, or attached to bracket 50 with only using at least one hand 66 of human operator 64 with no tool or special tool being required.

Referring to FIGS. 7-9, housing 18 of PDB 12 includes at least one printed circuit board (PCB) 68 disposed in housing 18. PCB 68 is generally parallel to ground surface 38 intermediate first and second opening 24, 26. PCB 68 is also at least a 6-layer printed circuit board. Alternately, the PCB may have any orientation within the housing of the PDB and be formed of any number of circuit board layers. PCB 68 is disposed in PDB 12 by being sandwiched, or trapped between upper and lower housing 19, 21 during construction of PDB 12 such that housings 19, 21 retain and mechanically stabilize PCB 68 in PDB 12. Alternately, PCB 68 may be fastened in housing any suitable fastener where the housing is preferably constructed to receive the fasteners. Plurality of electronic devices 14 are disposed on, or communicate in some manner with PCB 68 with a number of parts being soldered to PCB 68 before PCB 12 is constructed. PCB 68 may be formed from any suitable material, such as FR4 material, as is known in the electrical arts.

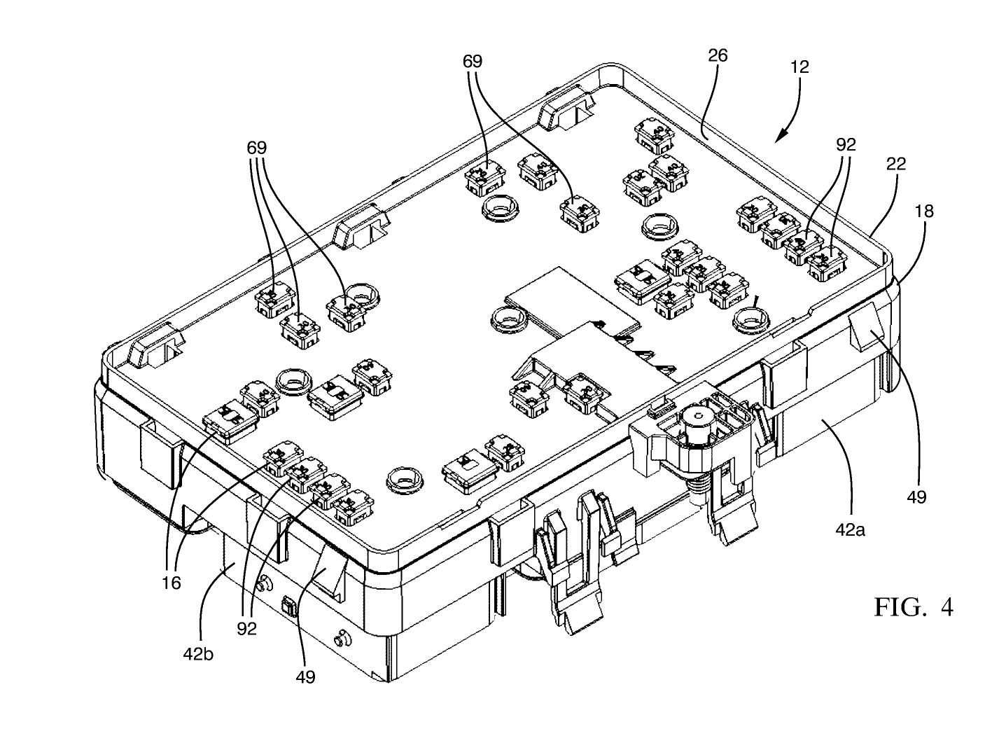

PCB 68 has a first external surface 70 and a second external surface 72 opposing first external surface 70. PCB 68 as a rectangular shape similar to that of PDB 12. Alternately, PCB may be any geometric shape. The PCB may also comprise multiple PCBs that are electrically connected in either parallel planes or disposed at adjoining, opposing, or perpendicular angles. Referring to FIG. 4, electronic devices 14 disposed proximate second surface 72 adjacent second opening 26 are only removable fuse electronic devices 69. Alternately, any type of removable electronic device may be disposed within the housing of the PDB adjacent the first and the second opening. Still yet alternately, any electronic device may be disposed on or about the PCB adjacent either the first or the second opening. PCB 68 includes circuit board trace 74 disposed on PCB 68 that electrically interconnects at least a portion of electrical devices 14 that form electronic circuits in PDB 12. Preferably, circuit board trace 74 is formed of copper alloy material and the copper alloy material that has a generally high mass density. A power source supplied for PCB 68 and plurality of electronic devices 14 is received via interface of bolt 51 with attachment of wire cable 40c thereat, as previously described herein. For example, the power source may be electrically transmitted within the PDB using a power bus bar formed by the circuit board trace on the PCB, or using an electrically-conductive wire conductor or a formed electrically-conductive metal piece, and the like.

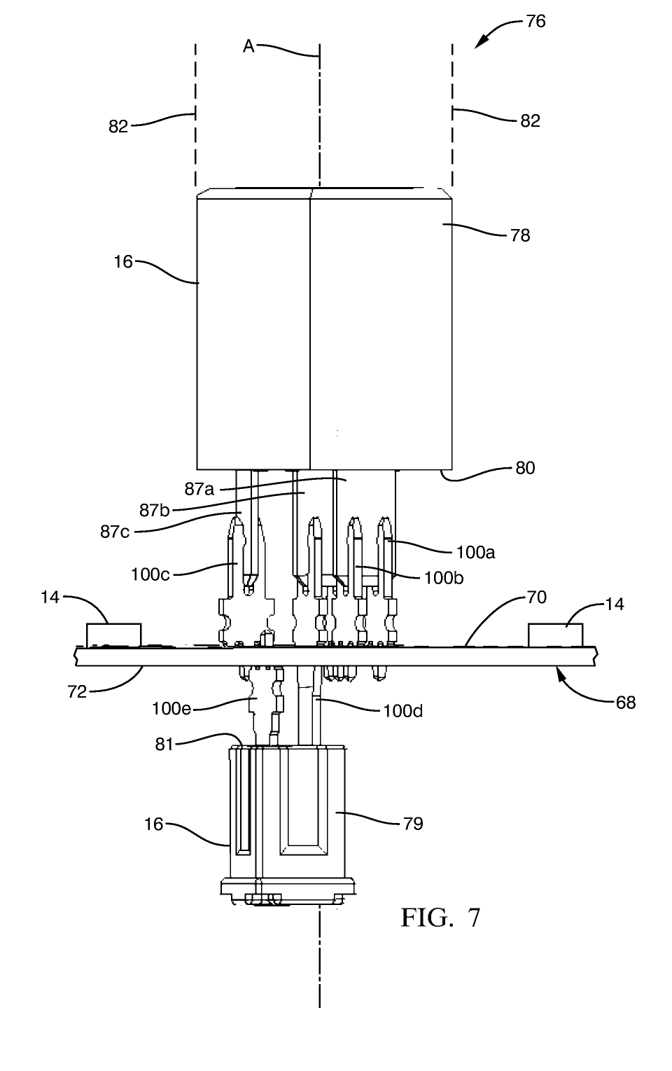

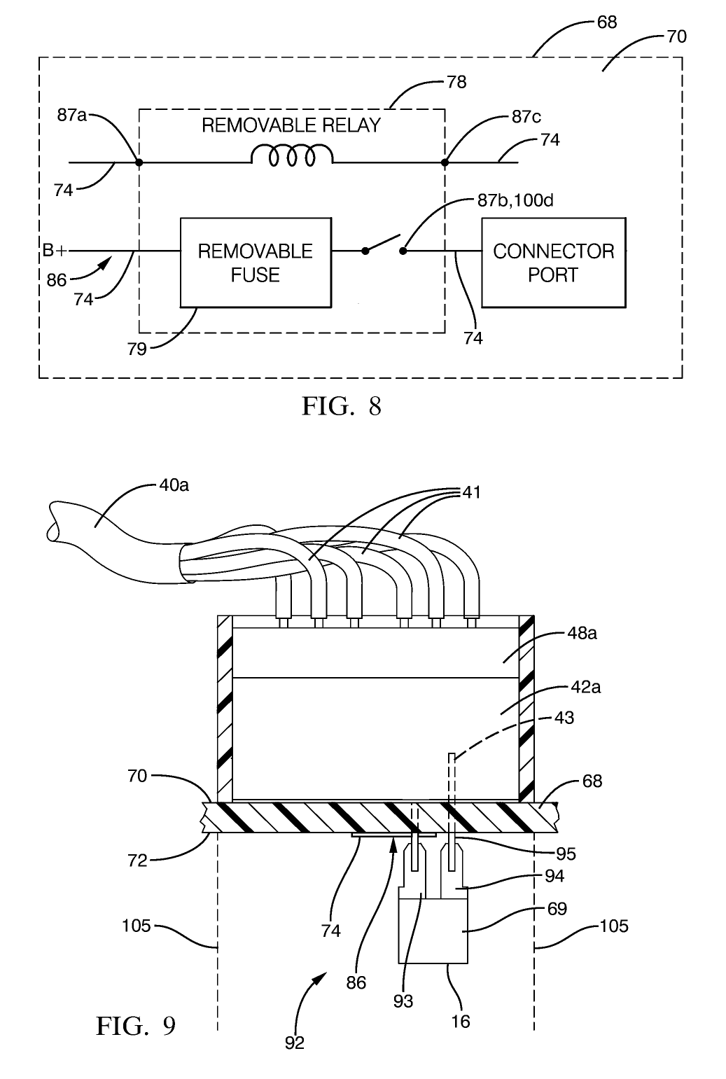

Referring again to FIGS. 7-8, at least one electronic circuit arrangement 76 disposed in housing 18 of PDB 12 and in communication with PCB 68 includes at least a first, or removable relay electronic device 78 and a second, or removable fuse electronic device 79 among removable electronic devices 16 disposed in PDB 12. Removable relay device 78 is disposed along a longitudinal axis A and fuse device 79 is opposingly axially spaced apart from relay device 78 with PCB 68 disposed intermediate devices 78, 79. Thus, relay device 78 is axially in-line with fuse device 79. Relay device 78 is disposed proximate first surface 70 of PCB 68 adjacent first opening 24 and fuse device 79 is disposed proximate second surface 72 of PCB 68 adjacent second opening 26. Removable relay device 78 includes male blade terminals 87a, 87b, 87c that face first surface 70 of PCB 68. Circuit board terminals 100a, 100b, 100c, 100d, 100e communicate with PCB 68. Terminals 100a, 100b, 100c have female terminations that receive blade terminals 87a, 87b, 87c of relay removable device 78. Terminal 100e is in electrical and mechanical communication with PCB 68 and with fuse removable device 79. Terminal 100d is a double-ended terminal as described above that passes through PCB 68 and electrically communicates with fuse removable device 79 and has a female termination that receives and electrically connects with male blade 87b. Terminal 100d is soldered to PCB 68 in a manner that does not include circuit board trace and the soldered terminal 100d is not in connection with circuit board trace. Thus, terminal 100d of removable fuse device 79 is axially aligned with blade terminal 87d of removable relay device 78 and forms the direct axial electrical connection between devices 78, 79. Arrangement 76 is in electrical communication with either wire cable 40a or 40b, or a combination of 40a and 40b. The direct axial electrical connection between devices 78, 79 extends through PCB 68 so as to not use circuit board trace. As previously described herein, reduction in the amount of circuit board trace results in PDB 12 having decreased weight, or mass as a result of reduction of copper material in the PDB that may allow for desired increased fuel efficiency for vehicle 30. Additionally, a reduction of copper material my advantageous realize a cost reduction to construct the PCB. Alternately, the removable relay and fuse devices may have any number of connections that communicate with the PCB, but still maintain the direct axial connection. Alternately, the fuse or the relay device may have any number of terminals that may be male or female mating to corresponding female or male terminals that are in communication with the PCB while retaining the axially aligned terminal that directly electrically connects at least a portion of the two removable devices.

Removable devices 78, 79 include respective device footprints 80, 81. Device footprint 80 of the removable relay device 78 defines a plane 82 that extends in a direction generally perpendicular to surfaces 70, 72 of PCB 68 where at least a portion of device footprint 81 of second removable device 79 disposed proximate second surface 72 lies within plane 82. Referring to FIG. 7, a substantial portion of footprint 81 of second removable device 79 lies within plane 82. Alternately, the footprint of the removable fuse device may lie completely within the footprint of the removable relay device. Still yet alternately, the footprint of the second removable device may lie completely within the footprint of the first removable device.

Referring to FIG. 3, when at least one electronic arrangement 76 includes more than one arrangement 76, a group 84 of arrangements is formed. Group 84 may be disposed adjacent the connector ports or anywhere in the PDB. Each arrangement 76 in group 84 is in communication with PCB 68 and has the respective axial electrical connection as previously described herein. Each electronic arrangement 76 in group 84 is also connected to a power source 86 received from mechanical bolt 53 through attached wire cable 40c, as also previously described herein. This useful electrical circuit arrangement results effectively utilizes space in PDB 12 while also attaining desired material savings for PDB 12 in that circuit board trace is not required for axially aligned terminal 100d as shown in FIG. 7. As previously described herein, less printed circuit board trace results in decreased material savings and decreased mass that may allow for increased fuel efficiency of vehicle 30. Referring to FIG. 11, using PDB 12 that includes at least one electrical circuit arrangement having at least one axially-aligned electrical connection is step 201 in method 200.

Referring to FIG. 9, PDB 12 also includes a portion of removable electronic devices 16 that are removable fuse electronic devices 69. At least one removable fuse electronic device 69 in the portion of removable fuse electronic devices 69 forms at least one electronic fuse circuit arrangement 92. Removable fuse 69 of arrangement 92 has an input 93 and an output 94. Input 93 is an input terminal of removable fuse 69 which is connected to power source 86 in PDB 12. Output 94 is an output terminal of removable fuse 69. Output 94 is connected with an electrically-conductive connecting terminal 95 and extends through PCB 68 into connector port 42. Terminal 95 is a double-ended terminal. One end of terminal 95 is terminal 43 associated with connector port 42. The other end of terminal 95 fits output 94 of fuse electronic device 69 of arrangement 92. Thus, the direct electrical connection using terminal 95 does communicates with PCB 68 in a manner that does require the use of circuit board trace. Terminal 95 may be soldered to PCB 68 to provide further mechanical support for terminal 95. Arrangement 92 is packaged underneath respective connector ports 42a, 42b to effectively use this space in PDB 12. Thus, PDB 12 may advantageously be able to fit more removable devices in a specified volume of space. Connector port 42a defines a plane 105 perpendicular to surfaces 70, 72 of PCB 68 such that at least a portion of removable fuse device 69 of arrangement 92 is disposed in plane 105. In one embodiment, this fuse arrangement may be utilized upwards of 8 times in the PDB and packaged beneath the connector ports to effectively use this packaging space while also not using circuit board trace to connect the respective outputs to separate terminals of the connector ports. Alternately, any number of fuse electronic arrangements may be packaged underlying the connector ports which may only be further limited by the amount of space disposed beneath the connector ports in combination with the ingenuity and creativity of the artesian in the electrical distribution center arts to fit them within this space. Using less circuit board trace may result in a PDB having lower mass which may translate into increased fuel efficiency for the vehicle.

PDB 12 is not in use in vehicle 30 when wire cable 40c is not connected to bolt 51 of PDB 12. PDB 12 is also not in use in vehicle 30 if wire cable 40c is connected to bolt 51 and both wire cable 40a and wire cable 40b are not connected to PDB 12.

PDB 12 is partially in use in vehicle 30 if wire cable 40c is connected to bolt 51 of PDB 12 and either wire cable 40a is connected to connector port 42a or wire cable 40b is connected to connector port 42b. When one of the wire cables 40a, 40b is connected to PDB 12 and the other one of the wire cables 40a, 40b is not connected to PDB 12, PDB 12 may partially electrically operate dependent on the electrical connections obtained through the connected wire cable.

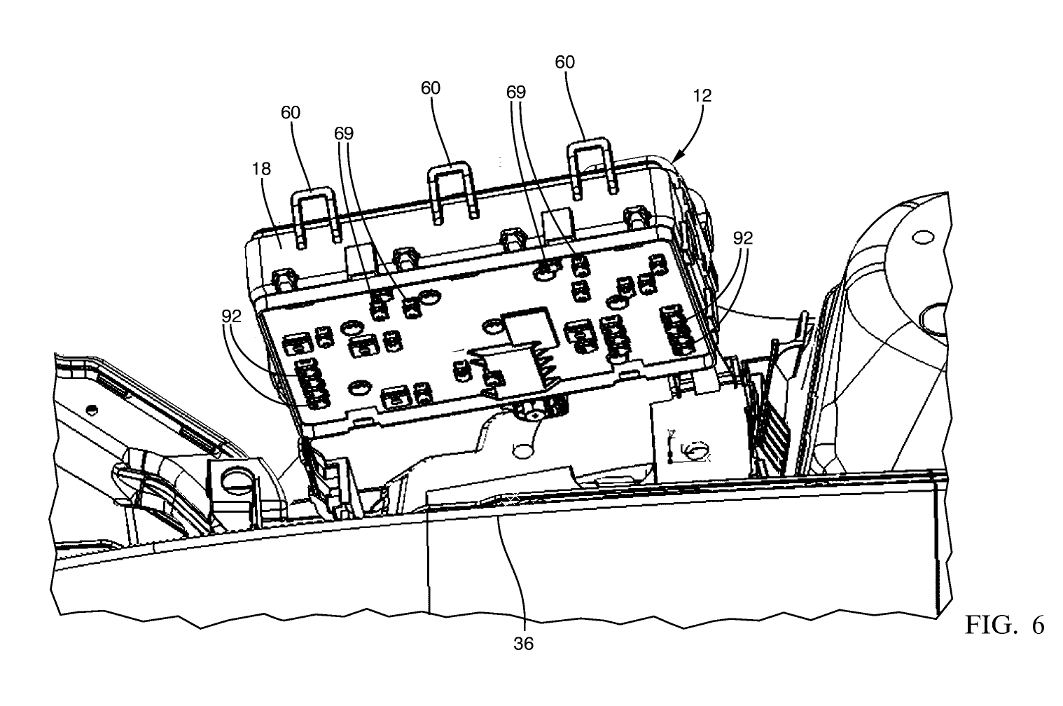

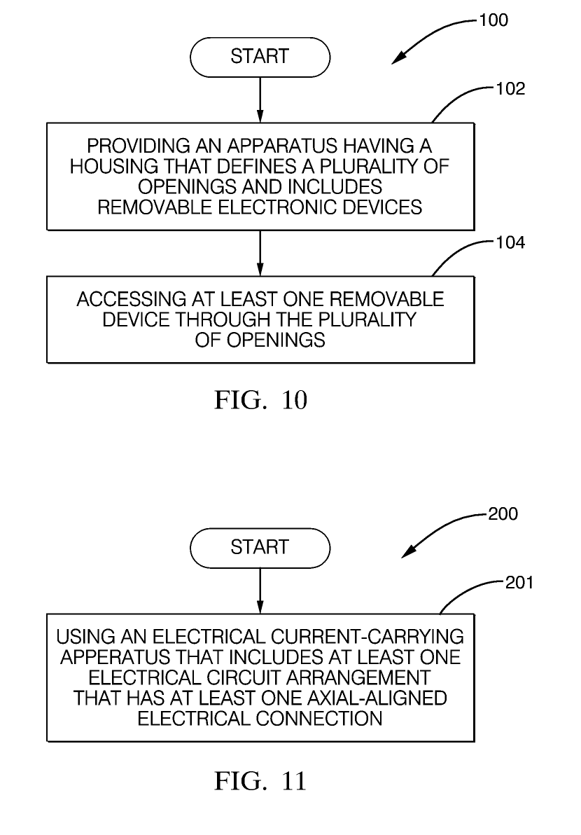

PDB 12 is completely in use when wire cables 40a, 40b, 40c in vehicle 30 are respectively electrically connected to connector ports 42a, 42b and to bolt 51 of PDB 12. Referring to FIG. 10, providing PDB 12 is step 102 of method 100. If at least one removable device 16 needs accessed through plurality of openings 24, 26, for example when a removable device 16 is deemed inoperative, removable device 16 is accessed through one of openings 24, 26 of PDB 12 while wire cables 40 remain attached to PDB 12 and electrically connect with at least one electronic device in plurality of electronic devices 14. Referring to FIG. 11, accessing at least one removable electronic device 16 through at least one of the plurality of openings 24, 26 external to housing 18 is step 104 of method 100. Gaining access to at least one of the openings in the plurality of openings 24, 26 of PDB 12 is a process. When PDB 12 is coupled in bracket 50, the process begins when PDB 12 is initially physically touched by at least one hand 66 of human operator 64. The process from the initial touch to accessing at least one removable device 16 through at least one of the plurality of openings 24, 26 by human operator 64 external to housing 18 is achieved, or attained by using at least one hand 66 of human operator 64. Thus, attaining access to openings 24, 26 is accomplished using only human hands 66 without having to use a tool. The process may be even more noticeable when removable fuse electronic devices 16 need accessed through second opening 26. This requires PDB 12 to be removed from bracket 50 and be moveable about wire cables 40 by human operator 64 to access either the first or the second opening 24, 26. Removable covers 56, 58 covering openings 24, 26 may be removed from openings 24, 26 by human hands 66 of human operator 64 by engaging respective latches 54. Wire cables 40 are sufficiently long, or have sufficient length even when coupled to PDB 12, so that when removable electronic devices 16 adjacent the first opening 24 require access, PDB 12 is freely movable about coupled wire cables 40 so that first opening 24 is positioned to face human operator 64. If removable devices 16 adjacent second opening 26 require access by human operator 64, second opening 26 is accessible to human operator 64 when PDB 12 is movingly flipped relative to first opening 24 about coupled wire cables 40 so that second opening 26 visually faces human operator 64. Moving flipping PDB 12 is a generally rotational movement about the coupled wire connectors, as best illustrated in FIG. 6. Additionally, accessing at least one removable electronic device 16 adjacent at least one of the plurality of openings 26, 28 is achieved by human operator 64 being disposed in a single stationary position adjacent engine compartment 32, as best illustrated in FIG. 1. This is a very useful feature for human operator 64 as removable devices 16 are accessible without human operator 64 having to establish multiple standing or other type of body positions to access removable electronic devices 16 which desirably reduces access and overall service time to service removable electronic devices 16. Alternately, the openings may be accessed using only a single human hand, although, the process to access the openings using the single human hand may take a longer time period to complete. For example, the process may be completed using only natural or artificial appendages on the single human hand.

Thus, a robust electrical current-carrying apparatus packages an increased amount of electronic components that are accessible thorough one of the plurality of openings in the apparatus. The apparatus is a power distribution box (PDB) in a power distribution system disposed in a vehicle. The removable devices are accessible through the plurality of openings regardless of the number of openings defined in the PDB and the removable devices are accessible while at least one wire cable is attached to the PDB remains attached in electrical communication with the PDB. Having a plurality of openings defined in the PDB allows for increased flexibility to access at least one of the plethora of removable electronic devices dispose in the PDB. Ensuring the PDB is attachable and unattachable from a bracket secured in an engine compartment of the vehicle without using a tool or a special tool saves time and effort to access and service the removable electronic devices. And because only at least one human hand of a human operator is required during a process to access the removable electronic devices in the PDB, the need to procure and provide the tools or special tools is eliminated. The removable electronic devices are accessed by also removing the removable covers that cover the respective plurality of openings. Removing the removable covers also only requires at least one human hand of the human operator using no tools or special tools. The PDB is disposed adjacent an exterior wall of the vehicle in the engine compartment such that the PDB is accessible by the human operator from a single stationary position adjacent the engine compartment. The removable electronic components adjacent the openings are easily accessed by flippingly movingly or orienting the PDB that has been removed from a bracket in the engine compartment to a position where the opening that needs to be accessed visually faces towards the human operator. The removable electronic devices adjacent the second opening are only removable fuse electronic devices increasing the likelihood of finding the removable fuse through the second opening in contrast to the first opening to further provide for additional ease in servicing the removable fuse devices. A portion of the housing of the PDB is formed of a first dielectric material so that connector ports on the PDB may withstand the larger applied mechanical forces to attach the connectors of the wire cables to the PDB to provide enhanced reliability for the PDB. One electrical circuit arrangement disposed in the PDB includes at least one removable relay and one removable fuse configured in a manner that a shared electrical connection between the removable relay and the removable fuse does not require the use of copper circuit board trace while increasing packaging efficiency. The increased packaging efficiency includes the implementation space being optimized by at least a portion of a footprint of one of the removable electronic devices residing within a plane of the other removable device's footprint on an opposing side of the PCB within the PDB. Another electronic circuit arrangement includes a fuse removable device that receives a power source through the fuse removable device that is directly electrically connected to a connector port of the PDB. Thus, an output of the removable fuse is directly electrically connected to a double-ended terminal that also serves as a terminal in the connector port which does not require the use of circuit board trace on the PCB. This fuse electronic circuit arrangement allows for packaging the fuse electronic arrangement in a packaging space of the PDB opposing the connector ports so that these fuse removable devices are accessible through the second opening of the PDB. This fuse electronic circuit arrangement allows for increased efficiency of packaging the PDB in an area underlying at least one of the connector ports. The wire cables are sealingly attached to the first wall of the PDB providing for a robust environmental seal of the wire cable to the PDB as well as providing a natural, gravity-draining drip-loop mechanization to reduce the possibility for environmental element intrusion in to the PDB over the service life of the vehicle.

While this invention has been described in terms of the one or more embodiments thereof, it is not intended to be so limited, but rather only to the extent set forth in the claims that follow.

It will be readily understood by those persons skilled in the art that the present invention is susceptible of broad utility and application. Many embodiments and adaptations of the present invention other than those described above, as well as many variations, modifications and equivalent arrangements, will be apparent from or reasonably suggested by the present invention and the foregoing description, without departing from the substance or scope of the present invention. Accordingly, while the present invention has been described herein in detail in relation to its preferred embodiment, it is to be understood that this disclosure is only illustrative and exemplary of the present invention and is made merely for purposes of providing a full and enabling disclosure of the invention. The foregoing disclosure is not intended or to be construed to limit the present invention or otherwise to exclude any such other embodiments, adaptations, variations, modifications and equivalent arrangements, the present invention being limited only by the following claims and the equivalents thereof.

We claim:

1. An electrical current-carrying apparatus comprising:
a housing including a plurality of electronic devices including removable electronic devices being disposed in the housing, the housing defining a plurality of openings so that the removable electronic devices are accessible through at least one of the plurality of openings, the housing being configured to receivably couple at least one wire cable so that the at least one coupled wire cable is in electrical communication with at least one electronic device in the plurality of electronic devices,
wherein when the at least one wire cable is coupled to the housing and the at least one removable device requires access, the at least one removable electronic device is accessed through at least one of the plurality of openings external to the housing while the at least one coupled wire cable remains attached to the housing.

2. The apparatus according to claim 1, wherein said access to each opening in the plurality of openings is attained by only using at least one hand of a human operator.

3. The apparatus according to claim 1, wherein the housing further includes,
a plurality of removable covers covering the respective plurality of openings where the covers are removable from the plurality of openings by disengagement from manually releasable clips.

4. The apparatus according to claim 1, wherein the apparatus contains at least two walls including a first wall and a second wall, and the plurality of openings include a first opening and a second opening, and the first wall defines the first opening and the second wall defines the second opening, and a first removable cover covers the first opening and a second removable cover covers the second opening, and the first and the second removable cover are releasably attached to the housing.

5. The apparatus according to claim 4, further including,
a bracket for receivably coupling the apparatus,
wherein the apparatus comprises a power distribution box (PDB) disposed in an engine compartment of the vehicle, the vehicle being disposed on a ground surface such that the first wall is remote from the ground surface in a direction generally perpendicular to the ground surface and the second wall is disposed intermediate the first wall and the ground surface.

6. The apparatus according to claim 5, wherein the plurality of electronic devices adjacent the second opening are only removable electronic devices.

7. The apparatus according to claim 6, wherein the removable electronic devices adjacent the second opening comprise only removable fuse electronic devices.

8. The apparatus according to claim 5, wherein the apparatus is disposed in the bracket and the at least one wire cable has sufficient length such that when the apparatus is removed from the bracket, the plurality of openings are made accessible to a human operator with the removable electronic devices adjacent the first opening being made accessible to the human operator when the apparatus is moved relative to the at least one coupled wire cable so that the first opening faces the human operator, and the removable electronic devices adjacent the second opening being made accessible to the human operator when the apparatus is movingly flipped relative to the first opening about the at least one coupled wire cable so that the second opening faces the human operator.

9. The apparatus according to claim 8, wherein either the first or the second opening is accessed, from when the apparatus is disposed in the bracket, using only at least one human hand of the human operator.

10. The apparatus according to claim 8, wherein the first and the second opening are accessed by the human operator disposed in a single stationary position adjacent the engine compartment.

11. The apparatus according to claim 5, wherein the at least one wire cable is attached to at least one connector port disposed along the first wall of the PDB.

12. The apparatus according to claim 4, wherein the first wall has a parallel, spaced relationship with the second wall and the apparatus further includes,
a printed circuit board (PCB) disposed in the housing intermediate the first opening and the second opening.

13. The apparatus according to claim 12, wherein the PCB includes circuit board trace disposed on the PCB that electrically interconnects at least a portion of the plurality of electronic devices, and at least one electronic circuit arrangement is disposed in the housing that includes at least two removable electronic devices in communication with the PCB and the at least two removable electronic devices include terminals where at least one terminal of one of the at least two removable electronic devices has axial electrical connection with at least one terminal of another one of the at least two removable devices so that said axial electrical connection of said at least one electronic circuit arrangement communicates with the PCB in a manner that does not use said circuit board trace.

14. The apparatus according to claim 13, wherein the at least two removable electronic devices include device footprints where a first removable device is disposed proximate a first surface of the PCB and a second removable device is disposed proximate a second surface of the PCB, and the second surface opposes the first surface such that the device footprint of the first removable device defines a plane extending in a direction generally perpendicular to the surfaces so that at least a portion of the device footprint of the second device lies within said plane.

15. The apparatus according to claim 14, wherein a substantial portion of the device footprint of the second removable device lies within said plane.

16. The apparatus according to claim 14, wherein the at least one electronic circuit arrangement comprises more than one electronic circuit arrangement to form a group, and the more than one arrangements in the group are in communication with the PCB, the arrangements in the group being disposed in the apparatus adjacent the at least one wire cable to directly electrically connect the respective arrangements of the group to the at least one wire cable so as to minimize use of said circuit board trace.

17. The apparatus according to claim 1, wherein the apparatus includes a PCB including circuit board trace and the apparatus includes at least one connector port that recievably couples the at least one wire cable, and a portion of the removable electronic devices comprise removable fuse devices, and a portion of the removable fuse devices are included as part of a removable fuse electronic circuit arrangement, the removable fuse electronic circuit arrangement including,
at least one removable fuse device having an input and an output;
a power source in electrical connection with the input; and
an electrically-conductive terminal in electrical connection with the output,
wherein the removable fuse electronic circuit arrangement is disposed in a position in the apparatus adjacent the at least one connector port such that the electrically-conductive terminal electrically connects the output to the at least one connector port.

18. The apparatus according to claim 17, wherein the at least one connector port includes a footprint having a surface area and the at least one removable fuse device includes a footprint having a surface area, and the surface area of the at least one connector port defines a plane in the apparatus therethrough such that the surface area of the footprint of at least one removable fuse device is at least partially disposed in said plane.

19. The apparatus according to claim 17, wherein the terminal comprises a double-ended terminal in mechanical connection with the PCB having ends, one end of the double-ended terminal being a terminal disposed within a connector port disposed on the apparatus and receiving a mating terminal disposed in a connector attached to the at least one wire cable and the other end the double-ended terminal receiving the at least one fuse removable device.

20. A method to access removable electronic devices in an electrical current-carrying apparatus, comprising:
providing the electrical current-carrying apparatus having a housing that defines a plurality of openings where the housing includes a plurality of electronic devices disposed within the housing and the plurality of electronic devices further include a plurality of removable electronic devices disposed adjacent the plurality of openings and adapted for accessibility through at least one of the plurality of openings external to the housing, and at least one wire cable is receivably coupled to the housing and in electrical communication with at least one electronic device in the plurality of electronic devices; and
accessing at least one removable electronic device in the plurality of removable electronic devices through the plurality of openings external to the housing while the at least one coupled wire cable remains coupled to the housing and in electrical communication with at least one electronic device in the plurality of electrical devices.

21. The method according to claim 20, wherein the apparatus comprises a power distribution box (PDB) disposed in a vehicle and the vehicle includes a bracket and the PDB is recievably coupled in the bracket, and the vehicle is disposed on a generally planar ground surface, and the PDB includes at least a first wall remote from the ground surface and a second wall intermediate the first wall and the ground surface, the plurality of openings including a first and a second opening, the first wall defining the first opening and the second wall defining the second opening, and the accessing step further includes,
removing the apparatus from the bracket,
moving the apparatus where the at least one coupled wire cable has sufficient length so that the first opening is orientated in relation to the at least one coupled wire cable to face a human operator when removable electronic devices adjacent the first opening require access, and
movingly flipping the apparatus in relation to the first opening about the at least one coupled wire cable so that the second opening faces the human operator when removable electronic devices adjacent the second opening require access.

22. An electrical current-carrying apparatus comprising:
at least one electronic circuit arrangement including at least a first and a second electronic device, the first electronic device being disposed along a longitudinal axis and the electronic devices including axial electrically-conductive device terminals,
wherein at least one device terminal of the first electronic device is in axial alignment with at least one device terminal of the second electronic device and in electrical communication therewith.

23. The apparatus according to claim 22, wherein the devices are removable electronic devices and the removable electronic devices are accessible external to the apparatus through at least one opening defined in the apparatus.

24. The apparatus according to claim 23, wherein the removable devices are accessed external to the apparatus through a plurality of openings defined in the apparatus.

25. The apparatus according to claim 24, wherein the first removable device is a removable relay device the second removable device is a removable fuse device.

26. The apparatus according to claim 22, wherein said electrical communication is associated with an electrically-conductive connecting terminal being in axial alignment with the at least one axial device terminal of the first electronic device and the at least one axial device terminal of the second electronic device and respective electrically connected therewith.

27. The apparatus according to claim 26, wherein the apparatus further includes,
a printed circuit board (PCB) disposed intermediate the first and the second device and the axial connecting terminal communicates with the PCB in a manner that does not use circuit board trace.

28. The apparatus according to claim 27, further including,
at least one wire cable attached to the apparatus,
wherein the at least one arrangement is disposed adjacent to the at least one wire cable.

29. The apparatus according to claim 22, further including,
at least one printed circuit board (PCB) disposed intermediate the electronic devices, and the at least one PCB includes external opposing surfaces where the first device has a footprint disposed proximate one of the surfaces and the second device has a footprint disposed proximate the other opposing surface,
wherein the footprint of the first electronic device defines a plane perpendicular to the surfaces so that at least a portion of the footprint of the second electronic device lies within said plane.

30. The apparatus according to claim 29, wherein a substantial portion of the footprint of the second electronic device lies within said plane.

31. The apparatus according to claim 22, wherein the apparatus comprises a power distribution box associated with a power distribution system disposed in a vehicle.

32. A method to operate an electrical current-carrying apparatus in an electrical application, comprising:
using the electrical current-carrying apparatus in the electrical application, the apparatus including,
at least one electronic circuit arrangement disposed in the electric current-carrying apparatus, said arrangement including at least a first and a second electronic device, and at least the first electronic device is disposed along a longitudinal axis and the electronic devices including axially-aligned electrically-conductive device terminals, and at least one axially-aligned device terminal of the first electronic device is in axial alignment with at least one axially-aligned device terminal of the second electronic device and in electrical communication therewith.

33. The method according to claim 32, wherein the apparatus comprises a power distribution box (PDB) and said electrical application comprises a power distribution system disposed in a vehicle that includes the PDB, and the PDB further includes,
at least one PCB including circuit board trace being disposed intermediate the first and the second electrical device in the PDB, and the at least one electronic circuit arrangement is in communication with the PCB in a manner that does not use said circuit board trace.
